(19) United States
(12) Patent Application Publication
(10) Pub. No.: US 2024/0248393 A1
(43) Pub. Date: Jul. 25, 2024

(54) IMPRINT METHOD, IMPRINT APPARATUS, DETERMINING METHOD, INFORMATION PROCESSING APPARATUS AND ARTICLE MANUFACTURING METHOD

(71) Applicant: CANON KABUSHIKI KAISHA, Tokyo (JP)

(72) Inventor: YOUSUKE KONDO, Tochigi (JP)

(21) Appl. No.: 18/418,963

(22) Filed: Jan. 22, 2024

(30) Foreign Application Priority Data
Jan. 24, 2023 (JP) 2023-008948

(51) Int. Cl. G03F 7/00

(52) U.S. Cl. CPC G03F 7/0002

(57) ABSTRACT

An imprint method of performing an imprint process of forming a pattern of an imprint material on a substrate by using a mold, the method including determining, before performing the imprint process, by using a function including, as variables, a pressure value applied to the mold, a pressure value applied to the substrate, and a relative tilt amount between the mold and the substrate, and expressing a contact position between the mold and the imprint material on the substrate, pressure values to be applied to the mold and the substrate, respectively, by a deformation unit and a relative tilt amount between the mold and the substrate to be adjusted by an adjustment unit such that a contact position to start a contact between the mold and the imprint material on the substrate matches a target position.

### BACKGROUND OF THE INVENTION

### Field of the Invention

The present invention relates to an imprint method, an imprint apparatus, a determining method, an information processing apparatus and an article manufacturing method.

### Description of the Related Art

In the manufacture of a semiconductor device, a MEMS, or the like, a processing apparatus that performs fine processing by discharging a discharge material (such as a liquid fluid) from a plurality of nozzles is used. As such the processing apparatus, for example, an imprint apparatus is known which forms a predetermined pattern by discharging, from nozzles, an uncured liquid fluid (imprint material) having a relatively high viscosity to arrange it on a substrate, and molding the imprint material on the substrate by using a mold. The imprint apparatus can form, on the substrate, a fine structure on the order of several nm.

As for the imprint apparatus, Japanese Patent No. 6647027 proposes a technique for generally avoiding contacting the imprint material on a substrate from the end portion of a mold, thereby promoting filling of the mold (pattern thereof) with the imprint material. Japanese Patent No. 6647027 discloses a technique for determining a condition for deforming the mold and the substrate upon pressing the mold against the imprint material on the substrate.

In the imprint apparatus, in order to implement more advantageous progress of filling of the mold with the imprint material, it is necessary to start contacting the imprint material on the substrate from a desired position of the mold. As compared to a full shot region where the shot region (the region to which the pattern of the mold is transferred) on the substrate is of the same size as the mold (pattern region thereof), this is particularly important in a partial shot region where the shot region is smaller than the mold.

### SUMMARY OF THE INVENTION

The present invention provides a new technique for implementing advantageous filling of a mold with an imprint material.

According to one aspect of the present invention, there is provided an imprint method of performing an imprint process of forming a pattern of an imprint material on a substrate by using a mold, the method including performing the imprint process while controlling a deformation unit configured to deform each of the mold and the substrate into a convex shape toward a space between the mold and the substrate by applying a pressure to each of the mold and the substrate, and an adjustment unit configured to adjust a relative tilt between the mold and the substrate, and determining, before performing the imprint process, by using a function including, as variables, a pressure value applied to the mold, a pressure value applied to the substrate, and a relative tilt amount between the mold and the substrate, and expressing a contact position between the mold and the imprint material on the substrate, pressure values to be applied to the mold and the substrate, respectively, by the deformation unit and a relative tilt amount between the mold and the substrate to be adjusted by the adjustment unit such that a contact position to start a contact between the mold and the imprint material on the substrate matches a target position.

Further aspects of the present invention will become apparent from the following description of exemplary embodiments with reference to the attached drawings.

### BRIEF DESCRIPTION OF THE DRAWINGS

FIG. 1 is a schematic view illustrating configurations of an imprint apparatus according to an aspect of the present invention.

FIG. 2 is a view illustrating an example of configurations of a mold holding mechanism.

FIG. 3 is a view illustrating an example of configurations of a substrate holding mechanism.

FIGS. 4A and 4B are views illustrating an example of configurations of a mold.

FIGS. 5A to 5D are views for describing an imprint process in the imprint apparatus illustrated in FIG. 1.

FIGS. 6A to 6D are views for describing an imprint process in the imprint apparatus illustrated in FIG. 1.

FIG. 7 is a view for describing the relationship between the pressure applied to the back surface space and the deformation amount of the mold.

FIG. 8 is a view for describing the relationship between the pressure applied to the substrate and the deformation amount of the substrate.

FIG. 9 is a flowchart for describing a process of determining a condition for controlling a pressure adjustment unit, a substrate chucking unit, and a mold driving unit.

FIGS. 10A and 10B are views each illustrating an example of a target position to start the contact between the mold and the imprint material on the substrate.

FIGS. 11A to 11F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

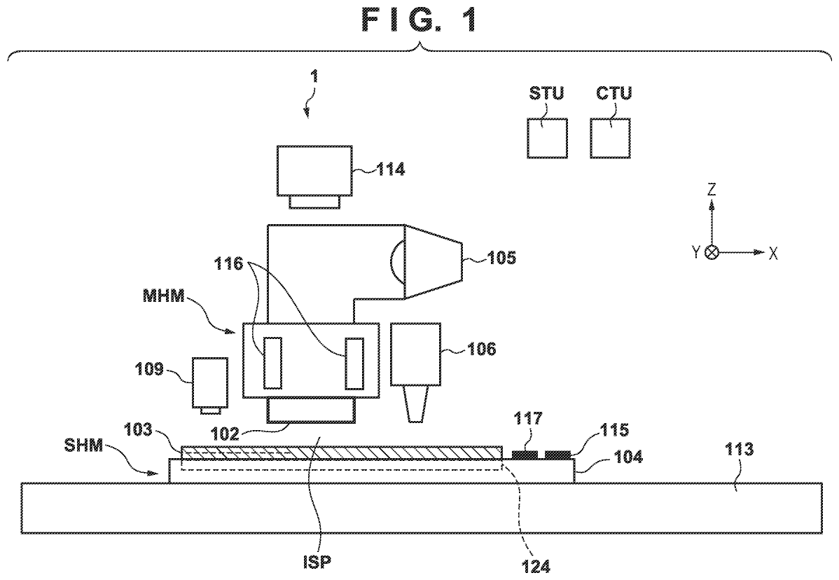

FIG. 1 is a schematic view illustrating configurations of an imprint apparatus 1 according to an aspect of the present invention. The imprint apparatus 1 is a lithography apparatus employed in a lithography step that is a manufacturing step for a device such as a semiconductor element, a liquid crystal display element, or magnetic storage medium as an article to form a pattern on a substrate. The imprint apparatus 1 brings an uncured imprint material arranged (supplied) on the substrate into contact with the mold, and applies curing energy to the imprint material, thereby forming a pattern of a cured product to which the pattern of the mold is transferred.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively.

In this embodiment, as a curing method of the imprint material, the imprint apparatus 1 employs a photo-curing method of curing the imprint material by irradiation of light such as ultraviolet light. However, the imprint apparatus 1 may employ a heat curing method of curing the imprint material by applying heat.

The imprint apparatus 1 includes a mold holding mechanism MHM, a substrate holding mechanism SHM, a substrate height measurement unit 109, a mold height measurement unit 117, a dispenser 106, a gas supply unit 125, an irradiation unit 105, an alignment scope 116, a storage unit STU, and a control unit CTU.

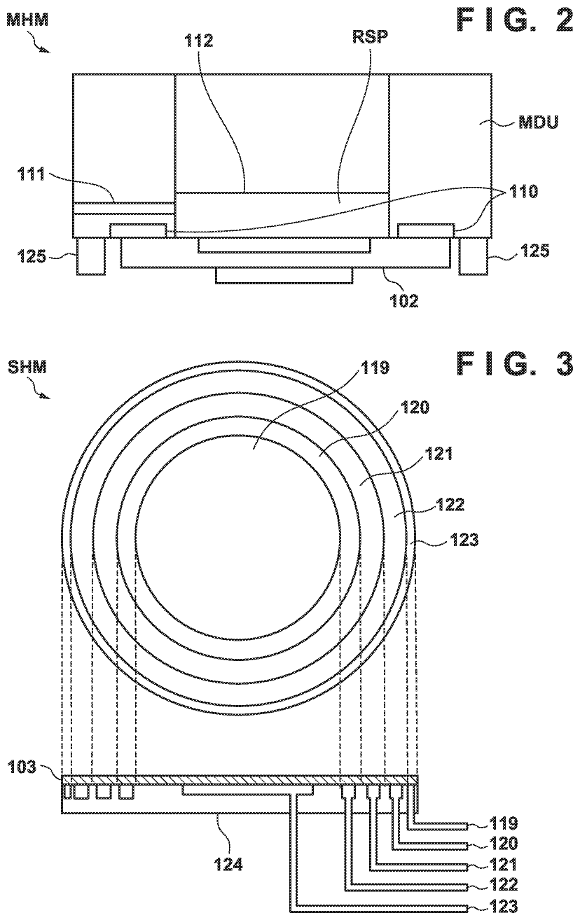

FIG. 2 is a view illustrating an example of configurations of the mold holding mechanism MHM. The mold holding mechanism MHM includes a mold holding unit 110, a pressure adjustment unit 111, and a mold driving unit MDU.

The mold holding unit 110 includes, for example, a mold chuck, and holds a mold 102 by chucking the mold 102.

The pressure adjustment unit 111 has a function of adjusting a pressure on the back surface (a surface on the opposite side of a pattern surface including a pattern region formed with a pattern) of the mold 102 held by the mold holding unit 110. In this embodiment, the pressure adjustment unit 111 can increase/decrease the pressure (atmospheric pressure) in a back surface space RSP defined by the back surface of the mold 102 and a seal glass 112. For example, when the pressure adjustment unit 111 locally increases the pressure in the back surface space RSP to become higher than the pressure in the apparatus, the mold 102 (pattern region thereof) can be deformed into a convex shape toward the side of a substrate 103. In this manner, the pressure adjustment unit 111 functions as a mold deformation mechanism that deforms the mold 102 into a convex shape toward the substrate 103 side by applying a pressure to the back surface of the mold 102.

The mold driving unit MDU has a function of driving the mold holding unit 110 (the mold 102 held by the mold holding unit 110) with respect to six axes that are the X-axis, the Y-axis, the Z-axis, and rotations about these axes. The mold driving unit MDU drives the mold holding unit 110 in the Z direction, thereby bringing the mold 102 into contact with the imprint material on the substrate or separating the mold 102 from the imprint material on the substrate. When bringing the mold 102 into contact with the imprint material on the substrate, the mold driving unit MDU can tilt (incline) the mold 102 with respect to the substrate 103. In this manner, the mold driving unit MDU functions as a mold driving mechanism that tilts the mold 102 with respect to the substrate 103 by driving the mold 102.

FIG. 3 is a view illustrating an example of configurations of the substrate holding mechanism SHM. The substrate holding mechanism SHM includes substrate chucking units 119, 120, 121, 122, and 123, a substrate chuck 124, and a substrate stage 104.

Each of the substrate chucking units 119 to 123 is connected to a pressure supply mechanism (not shown), and has a function of supplying (generating) a positive pressure or a negative pressure between a pressure supply end on the substrate side, more specifically, the substrate chuck 124, and the substrate 103 (back surface thereof) placed on the substrate chuck 124. For example, each of the substrate chucking units 119 to 123 supplies a negative pressure to the pressure supply end on the substrate side, thereby chucking the substrate 103 placed on the substrate chuck 124 (that is, holds the substrate 103 via the substrate chuck 124). Further, each of the substrate chucking units 119 to 123 can deform the substrate 103 placed on the substrate chuck 124 into a convex shape toward the mold 102 side by supplying a positive pressure to the pressure supply end on the substrate side. In this manner, each of the substrate chucking units 119 to 123 functions as a substrate deformation mechanism that deforms the substrate 103 into a convex shape toward the mold 102 side by applying a pressure to the back surface of the substrate 103.

The substrate stage 104 supports the substrate chuck 124. The substrate stage 104 includes a substrate driving unit (not shown), and is configured to be capable of driving on a stage base 113 (on the X-Y plane). The substrate driving unit has a function of driving the substrate stage 104 (substrate 103) with respect to six axes that are the X-axis, the Y-axis, the Z-axis, and rotations about these axes.

The substrate height measurement unit 109 includes, for example, an optical distance measurement sensor, and measures the height (Z-direction position) of the substrate 103 with respect to an imprint reference plane. Here, the imprint reference plane is a plane serving as the reference upon bringing the mold 102 into contact with the imprint material on the substrate and pressing the mold 102 against the imprint material. More specifically, if the imprint apparatus 1, the mold 102, and the substrate 103 are as designed, the imprint reference plane is an ideal plane for filling of the mold 102 (pattern thereof) with the imprint material on the substrate.

The mold height measurement unit 117 includes, for example, an optical distance measurement sensor, and measures the height (Z-direction position) of the mold 102 with respect to the imprint preference plane.

The dispenser 106 has a function of arranging (supplying) the imprint material on the substrate 103. The dispenser 106 includes, for example, a nozzle unit that discharges the imprint material, a supply unit that supplies the imprint material to the nozzle unit, and a driving unit that enables translation driving and rotational driving of the nozzle unit in the X, Y, and Z directions. In the dispenser 106, a large number of (for example, several thousands) discharge holes for discharging the imprint material are formed in the nozzle unit.

The gas supply unit 125 supplies a gas to an imprint space ISP between the mold 102 and the substrate 103, thereby filling the imprint space ISP with the gas. For example, the gas supply unit 125 fills the imprint space ISP with helium. With this, when pressing the mold 102 against the imprint material on the substrate, helium escapes from the imprint space ISP through the mold 102. Thus, the fillability of the imprint material with respect to the mold 102 can be improved. In addition, when curing the imprint material on the substrate, occurrence of curing defects of the imprint material due to oxygen inhibition can be suppressed. The supply amount of gas supplied from the gas supply unit 125 to the imprint space ISP is adjusted (optimized) in accordance with the volume of the imprint space ISP (the gap amount between the mold 102 and the substrate 103) such that the number of curing defects (defect amount) of the imprint material falls within an allowable range.

The irradiation unit 105 includes, for example, a light source that emits light (such as ultraviolet light) including a wavelength which cures the imprint material on the substrate, and an optical system that guides the light emitted from the light source to the imprint material on the substrate. The irradiation unit 105 applies the light emitted from the light source to the imprint material on the substrate via the mold 102.

The alignment scope 116 detects a mold-side mark (alignment mark) provided on the mold 102, a substrate-side mark provided on the substrate 103, and a reference mark 115 provided on the substrate stage 104, and measures the relative position among them. A light position detection apparatus as disclosed in Japanese Patent Laid-Open No. 2008-509825 is used for the alignment scope 116. For example, by employing, for the alignment scope 116, a method of detecting a moire signal reflecting the relative position between two marks, a high measurement accuracy can be implemented with a simple optical system. By employing a scope with a low resolution (NA) and arranging a plurality of scopes as the alignment scope 116, it is possible to simultaneously detect the substrate-side marks provided in the four corners of a shot region on the substrate.

The storage unit STU includes a storage device such as an RAM, a ROM, or a hard disk. The storage unit STU stores (memories) a program to be executed by the control unit CTU, various kinds of data, information, a function, and the like.

The control unit CTU is formed from, for example, a computer (information processing apparatus) including a CPU, a memory, and the like. The control unit CTU operates the imprint apparatus 1 by comprehensively controlling respective units of the imprint apparatus 1 in accordance with a program stored in the storage unit STU or the like. For example, the control unit CTU performs an imprint process of forming a pattern of the imprint material on the substrate by using the mold 102.

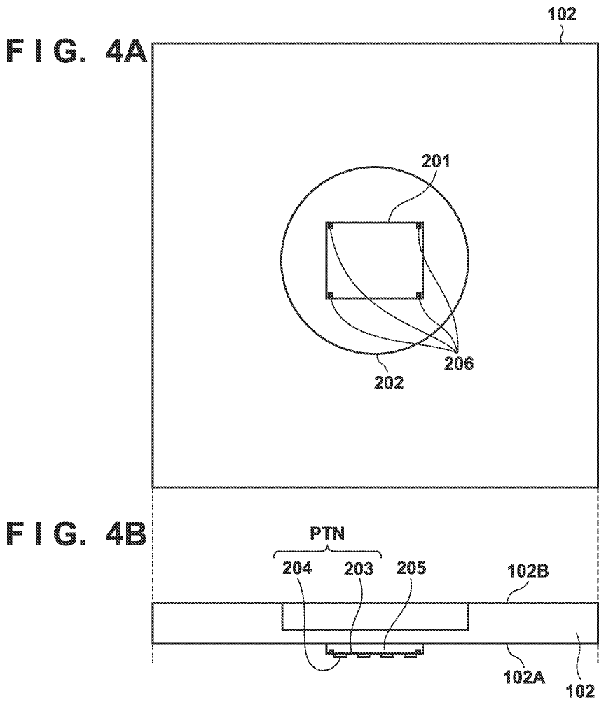

FIGS. 4A and 4B are views illustrating an example of configurations of the mold 102. FIG. 4A is a plan view of the mold 102, and FIG. 4B is a sectional view of the mold 102. The mold 102 is made of fused quartz, an organic polymer, a metal, or the like, but not limited to these materials.

The mold 102 includes a recessed portion 202 (cavity) in the central portion of a back surface 102B (second surface) on the opposite side of a pattern surface 102A (first surface) including a pattern region 201 with a pattern formed therein. The recessed portion 202 is formed by digging the back surface 102B, and has a depth of, for example, about 1 mm.

In the central portion of the pattern surface 102A of the mold 102, the pattern region 201 is formed so as to correspond to the recessed portion 202. The pattern region 201 includes a base 205, and a pattern PTN formed by a groove 203 and a projection 204 provided on the base 205. The base 205 has a thickness of, for example, about 30 μm. In this embodiment, the pattern PTN is formed as a minute pattern of about several nm to 10-odd nm. In this case, the depth of the groove 203 (the distance between the groove 203 and the projection 204) is about several ten nm to several hundred nm. Further, mold-side marks 206 are provided in the four corners of the pattern region 201 (base 205) as the alignment marks to be detected by the alignment scope 116.

Next, an imprint process as a process of forming a pattern on the substrate in the imprint apparatus 1 will be described.

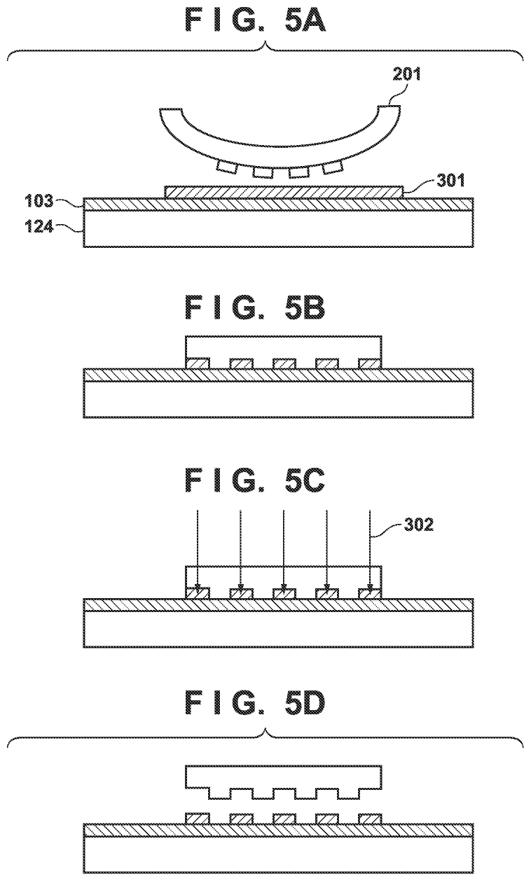

With reference to FIGS. 5A to 5D, an imprint process with respect to a full shot region where the shot region (the region to which the pattern PTN of the mold 102 is transferred) on the substrate is of the same size as the pattern region 201 of the mold 102 will be described. Note that the full shot region can also be considered as the shot region having the same area as the pattern region 201 of the mold 102. In the imprint process with respect to the full shot region, the pattern PTN of the mold 102 is transferred to an imprint material 301 on the substrate while deforming the pattern region 201 (pattern PTN) of the mold 102 but not deforming the substrate 103.

First, while supplying helium from the gas supply unit 125, the imprint material 301 is discharged from the dispenser 106 to arrange (apply) the imprint material 301 in the shot region on the substrate. Then, as shown in FIG. 5A, in a state in which the pattern region 201 of the mold 102 is deformed into a convex shape toward the substrate 103 side, the mold 102 is brought close to the substrate 103 to bring the mold 102 into contact with the imprint material 301 on the substrate. Note that about several hundred msec is required to deform the pattern region 201 of the mold 102 into a predetermined shape by adjusting the pressure in the back surface space RSP of the mold 102 by the pressure adjustment unit 111. However, by performing deformation of the pattern region 201 of the mold 102 and arrangement of the imprint material 301 on the substrate in parallel, a decrease in productivity can be suppressed. Further, when bringing the mold 102 close to the substrate 103, a contact (imprint) start position is set at a position offset to the mold 102 side by about 10 μm from the height of the substrate 103 measured by the substrate height measurement unit 109. By driving the mold 102 at high speed until reaching the contact start position, and driving the mold 102 at low speed after reaching the contact start position, a decrease in productivity can be suppressed while preventing damage of the mold 102 caused by the contact between the mold 102 and the substrate 103.

Then, as shown in FIG. 5B, when the imprint material 301 on the substrate and the mold 102 come into contact with each other, the mold 102 is returned to the original shape, and the pattern PTN (groove 203) of the mold 102 is filled with the imprint material 301.

Then, as shown in FIG. 5C, in the state in which the imprint material 301 on the substrate and the mold 102 are in contact with each other, light 302 is applied from the irradiation unit 105, thereby curing the imprint material 301 on the substrate.

Then, as shown in FIG. 5D, the mold 102 is moved away from the substrate 103 to separate the mold 102 from the cured imprint material 301 on the substrate. With this, the pattern PTN of the mold 102 is transferred to the imprint material 301 on the substrate. By performing an etching process in a post-processing apparatus (not shown) while using, as a mask, the imprint material 301 with the pattern PTN of the mold 102 transferred thereto, and removing the imprint material 301 from the substrate 103, the pattern PTN of the mold 102 is transferred to the substrate 103.

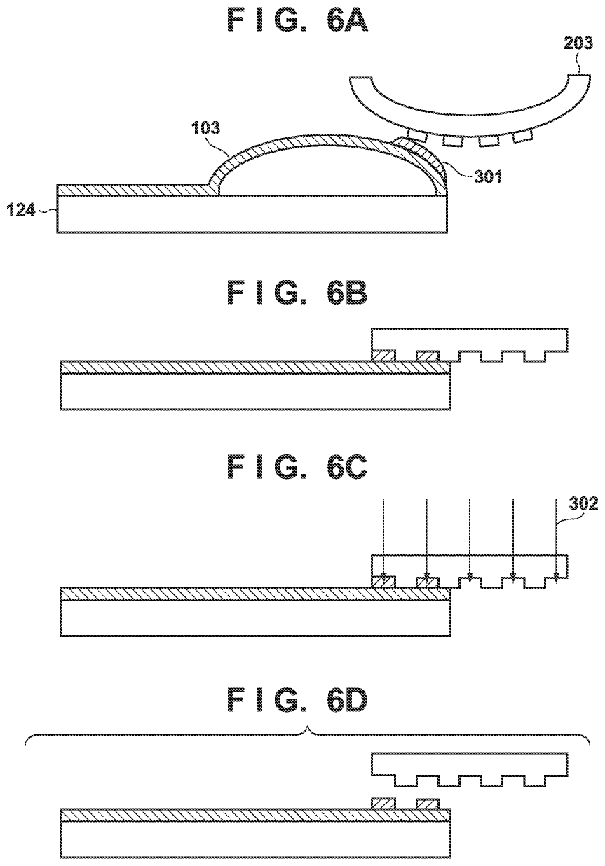

With reference to FIGS. 6A to 6D, an imprint process with respect to a partial shot region where the shot region on the substrate is smaller than the pattern region 201 of the mold 102 will be described. Note that the partial shot region can also be considered as the shot region having a smaller area than the pattern region 201 of the mold 102. In the imprint process with respect to the partial shot region, the pattern PTN of the mold 102 is transferred to the imprint material 301 on the substrate while deforming the pattern region 201 (pattern PTN) of the mold 102 and the substrate 103.

First, while supplying helium from the gas supply unit 125, the imprint material 301 is discharged from the dispenser 106 to arrange (apply) the imprint material 301 in the shot region on the substrate. Then, as shown in FIG. 6A, in a state in which the pattern region 201 of the mold 102 is deformed into a convex shape toward the substrate 103 side and the substrate 103 is deformed into a convex shape toward the mold 102 side, the mold 102 is brought close to the substrate 103 to bring the mold 102 into contact with the imprint material 301 on the substrate. As has been described above, about several hundred msec is required to deform the pattern region 201 of the mold 102 into a predetermined shape by adjusting the pressure in the back surface space RSP of the mold 102 by the pressure adjustment unit 111. However, by performing deformation of the pattern region 201 of the mold 102, deformation of the substrate 103, and arrangement of the imprint material 301 on the substrate in parallel, a decrease in productivity can be suppressed. Similarly, a contact start position is set at a position offset to the mold 102 side by about 10 μm from the height of the substrate 103 measured by the substrate height measurement unit 109.

Then, as shown in FIG. 6B, when the imprint material 301 on the substrate and the mold 102 come into contact with each other, each of the mold 102 and the substrate 103 is returned to the original shape, and the pattern PTN (groove 203) of the mold 102 is filled with the imprint material 301.

Then, as shown in FIG. 6C, in the state in which the imprint material 301 on the substrate and the mold 102 are in contact with each other, the light 302 is applied from the irradiation unit 105, thereby curing the imprint material 301 on the substrate.

Then, as shown in FIG. 6D, the mold 102 is moved away from the substrate 103 to separate the mold 102 from the cured imprint material 301 on the substrate. With this, the pattern PTN of the mold 102 is transferred to the imprint material 301 on the substrate. By performing an etching process in the post-processing apparatus (not shown) while using, as a mask, the imprint material 301 with the pattern PTN of the mold 102 transferred thereto, and removing the imprint material 301 from the substrate 103, the pattern PTN of the mold 102 is transferred to the substrate 103.

Note that in this embodiment, a case in which the substrate 103 is deformed in the imprint process with respect to the partial shot region has been described as an example, but the present invention is not limited to this. For example, the substrate 103 may be deformed also in the imprint process with respect to the full shot region.

In the imprint process as described above, in order to implement more advantageous progress of filling of the mold 102 with the imprint material 301, it is necessary to start contacting the imprint material 301 on the substrate from a desired position of the mold 102. This is particularly important in the partial shot region where the shot region on the substrate is smaller than the mold 102.

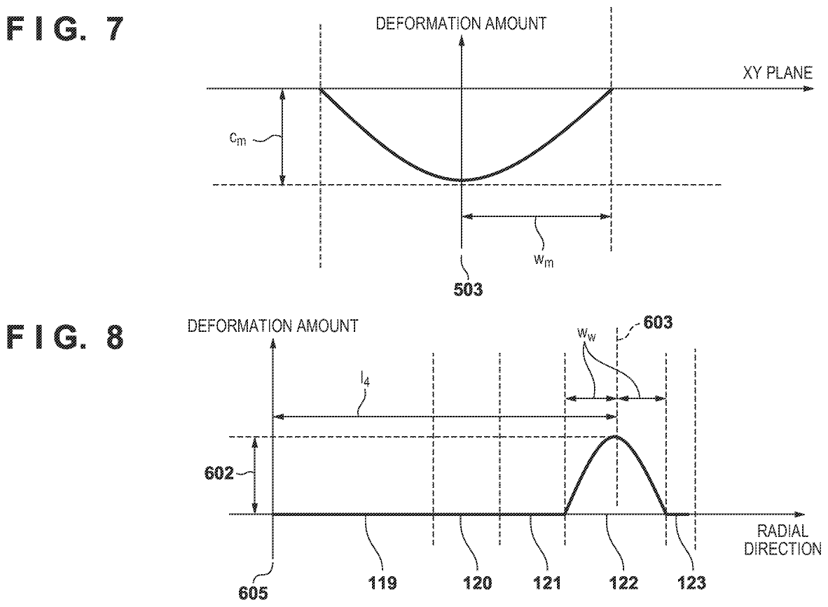

With reference to FIG. 7, the relationship between the pressure applied to the back surface space RSP and the deformation amount of the mold 102 (pattern region 201) in a case of deforming the mold 102 into a convex shape toward the substrate 103 side by applying the pressure to the back surface 102B of the mold 102, that is, the back surface space RSP will be described. Let Wₘ [mm] be the radius, in the X-Y plane, of the back surface space RSP defined by the back surface of the mold 102 and the seal glass 112, and aₘ [μm/kPa] be the deformation amount of a center portion 503 of the mold 102 per unit pressure applied to the bask surface space RSP. Further, let cₘ [μm] be the deformation amount of the center portion 503 of the mold 102 upon applying the pressure to the back surface space RSP with a pressurizing amount (pressure value) pₘ [kPa], and (xₘ, yₘ) [mm] be the position from the center portion 503 of the mold 102. In this case, the deformation amount fₘ (xₘ, yₘ) of the mold 102 is expressed by:

$$\{ \begin{matrix}{f}_{m} ( {x}_{m} , {y}_{m} ) = - \frac{{c}_{m}}{{w}_{m}^{2}} {x}_{m}^{2} - \frac{{c}_{m}}{{w}_{m}^{2}} {y}_{m}^{2} + {c}_{m} when {w}_{m} ≦ \sqrt{{x}_{m}^{2} + {y}_{m}^{2}} \\ {f}_{m} ( {x}_{m} , {y}_{m} ) = 0 when {w}_{m} > \sqrt{{x}_{m}^{2} + {y}_{m}^{2}}\end{matrix} \qquad ( 1 )$$

$$where {c}_{m} = {a}_{m} \cdot {p}_{m}$$

With reference to FIG. 8, the relationship between the pressure applied to the substrate 103 and the deformation amount of the substrate 103 in a case of deforming the substrate 103 into a convex shape toward the mold 102 side by applying the pressure to the substrate 103 (back surface thereof) will be described. Here, a case in which the pressure is applied to the substrate 103 via the substrate chucking unit 122 and the substrate 103 is chucked with a negative pressure via each of the substrate chucking units 119, 120, 121, and 123 will be described as an example. Let 14 be the distance from a center portion 605 of the substrate 103 to a center portion 603 of the substrate chucking unit 122, and W_{w} [mm] be the distance from the center portion 603 of the substrate chucking unit 122 to the boundary of the substrate chucking unit 122. Further, let aw [μm/kPa] be the deformation amount of the center portion 603 of the substrate chucking unit 122 per unit pressure applied to the substrate chucking unit 122, and c_{w} [μm] be the deformation amount of the center portion 603 of the substrate chucking unit 122 upon applying the pressure with a pressurizing amount (pressure value) p_{w} [kPa]. Let (x_{w}, y_{w}) [mm] be the position from the center portion 605 of the substrate 103. In this case, deformation g(r_{w}) of the substrate 103 is expressed by:

$$\{ \begin{matrix}g ( {r}_{w} ) = - \frac{{c}_{w}}{{w}_{w}^{2}} {( {r}_{w} - {l}_{4} )}^{2} + {c}_{w} when {w}_{w} > \vert {r}_{w} - {l}_{4} \vert \\ g ( {r}_{w} ) = 0 when {w}_{w} ≦ \vert {r}_{w} - {l}_{4} \vert\end{matrix} \qquad ( 2 )$$

$$where {c}_{w} = {a}_{w} \cdot {p}_{w} , {r}_{w} = \sqrt{{x}_{w}^{2} + {y}_{w}^{2}} , {a}_{w} < 0$$

Next, a method of obtaining the contact start point to start the contact between the imprint material on the substrate and the mold 102 will be described. The coordinate reference in equation (1) is set at the center portion 605 of the substrate 103, and a gap h(r_{w}, θ) between the mold 102 and the substrate 103 considering the tilt amount (tilt X (tₓ), tilt Y (t_{y})) of the mold 102 with respect to the substrate 103 is obtained from:

$$h ( {r}_{w} , θ ) = f ( {r}_{w} , θ ) - g ( {r}_{w} ) \qquad ( 3 )$$

$$\{ \begin{matrix}\begin{matrix}f ( {r}_{w} , θ ) = - \frac{{c}_{m}}{{w}_{m}^{2}} {( {r}_{w} * cos θ - {l}_{x} )}^{2} - \frac{{c}_{m}}{{w}_{m}^{2}} {( {r}_{w} * sin θ - {l}_{y} )}^{2} + \\ \begin{matrix}{t}_{x} ( {r}_{w} * cos θ - {l}_{x} ) + {t}_{y} ( {r}_{w} * sin θ - {l}_{x} ) - {c}_{m} + {c}_{w} \\ when {w}_{m} ≦ \sqrt{{( {r}_{w} * cos θ - {l}_{x} )}^{2} + {( {r}_{w} * sin θ - {l}_{y} )}^{2}}\end{matrix}\end{matrix} \\ f ( {r}_{w} , θ ) = - {c}_{m} + {c}_{w} when {w}_{m} > \sqrt{{( {r}_{w} * cos θ - {l}_{x} )}^{2} + {( {r}_{w} * sin θ - {l}_{y} )}^{2}}\end{matrix}$$

$$where θ = {tan}^{- 1} \frac{{y}_{w}}{{x}_{w}}$$

Note that (lₓ, l_{y}) indicates the position, in the substrate, of the shot region to which the pattern of the mold 102 is transferred.

The mold 102 is deformed into a convex shape toward the substrate 103 side with the pressurizing amount pₘ [kPa], and the substrate 103 is deformed into a convex shape toward the substrate 102 side with the pressurizing amount p_{w} [kPa]. Hence, the contact start point between the imprint material on the substrate and the mold 102 is obtained by r_{w} and θ satisfying equation (4) described below. r_{w} and θ are obtained using pₘ, p_{w}, tₓ, and t_{y} as variables.

$$\{ \begin{matrix}{r}_{w} = p ( {p}_{m} , {p}_{w} , {t}_{x} , {t}_{y} ) \\ θ = q ( {p}_{m} , {t}_{x} , {t}_{y} )\end{matrix} \qquad ( 4 )$$

Therefore, in this embodiment, equation (4) is stored in the storage unit STU as a function expressing the contact position between the mold 102 and the imprint material on the substrate. Here, equation (4) is a function including, as variables, the pressure value (pₘ) applied to the mold 102 (back surface thereof (back surface space RSP)), the pressure value (p_{w}) applied to the substrate 103 (back surface thereof), and the relative tilt amount (tₓ, t_{y}) between the mold 102 and the substrate 103. The control unit CTU determines, by using the function stored in the storage unit STU, a condition for controlling the pressure adjustment unit 111, the substrate chucking units 119 to 123, and the mold driving unit MDU such that the contact position to start the contact between the mold 102 and the imprint material on the substrate matches the target position.

In this embodiment, the pressure adjustment unit 111 and the substrate chucking units 119 to 123 function as a deformation unit that deforms each of the mold 102 and the substrate 103 into a convex shape toward the imprint space ISP side by applying pressures to the mold 102 and the substrate 103. Therefore, as a condition for controlling the pressure adjustment unit 111 and the substrate chucking units 119 to 123, a pressure value to be applied to the back surface of the mold 102 by the pressure adjustment unit 111, and pressure values to be applied to the back surface of the substrate 103 by the substrate chucking units 119 to 123 in the imprint process are determined.

Further, in this embodiment, the mold driving unit MDU functions as an adjustment unit that adjusts the relative tilt between the mold 102 and the substrate 103. Therefore, as a condition for controlling the mold driving unit MDU, the tilt amount of the mold 102 by which the mold driving unit MDU should tilt the mold 102 with respect to the substrate 103 (the relative tilt amount between the mold 102 and the substrate 103) in the imprint process is determined.

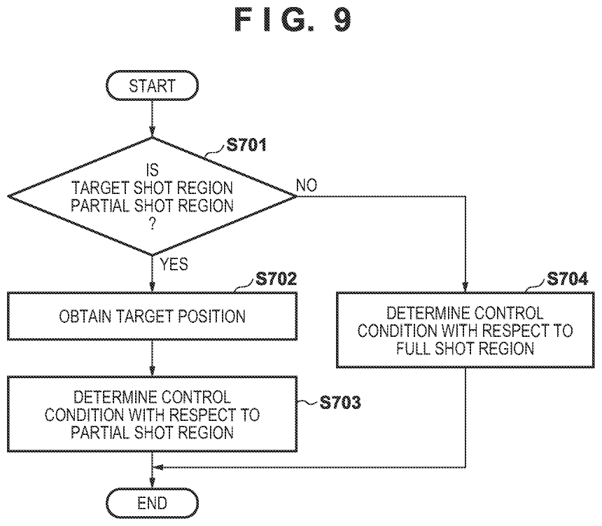

With reference to FIG. 9, a process (determination method) of determining a condition (control condition) for controlling the pressure adjustment unit 111, the substrate chucking units 119 to 123, and the mold driving unit MDU will be described. As has been described above, this process is performed by the control unit CTU for each shot region on the substrate on which the imprint process is performed, that is, for each of a plurality of shot regions. In the following description, among the plurality of shot regions on the substrate, the shot region for which the condition for controlling the pressure adjustment unit 111, the substrate chucking units 119 to 123, and the mold driving unit MDU is referred to as a target shot region.

In step S701, it is determined whether the target shot region is the partial shot region. In this embodiment, by specifying the partial shot region based on information indicating the array of the plurality of shot regions on the substrate, it is determined whether the target shot region is the partial shot region. If the target shot region is the partial shot region, the process transitions to step S702. On the other hand, if the target shot region is not the partial shot region, that is, if the target shot region is the full shot region, the process transitions to step S704.

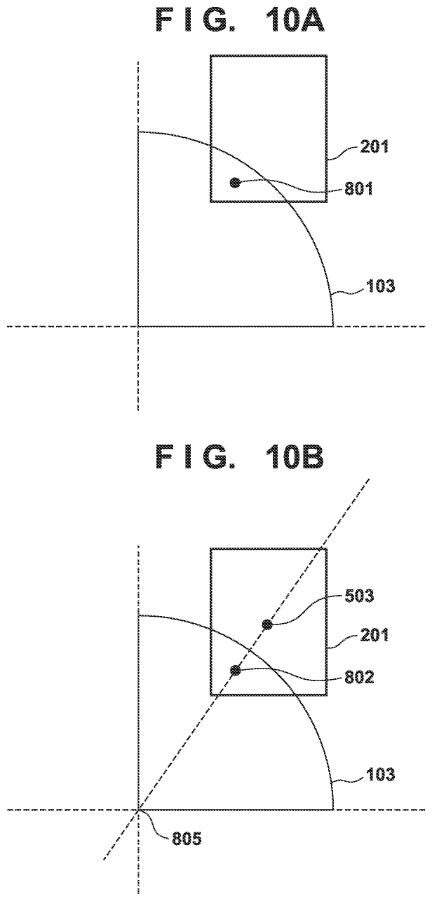

In step S702, in the imprint process with respect to the target shot region (partial shot region), a target position (X_{d}, Y_{d}) [mm] to start the contact between the mold 102 and the imprint material upon bringing the mold 102 and the imprint material on the target shot region into contact with each other is obtained. For example, as shown in FIG. 10A, a centroid position 801 of the target shot region (partial shot region) on the substrate is conceivable as the target position. Alternatively, for example, as shown in FIG. 10B, a middle point 802 in the target shot region located on a line connecting the center portion 503 of the mold 102 (pattern region 201 thereof) and a center portion 805 of the substrate 103 is conceivable as the target position. FIGS. 10A and 10B are views each illustrating an example of the target position to start the contact between the mold 102 and the imprint material on the substrate.

In step S703, by using the function (equation (4)) stored in the storage unit STU, a control condition in the imprint process is determined such that the contact position to start the contact between the mold 102 and the imprint material on the substrate matches the target position obtained in step S702. More specifically, as the control condition in the imprint process, a pressure value (pressurizing amount pₘ [kPa]) to be applied to the back surface of the mold 102 by the pressure adjustment unit 111, and pressure values (pressurizing amounts pw [kPa]) to be applied to the back surface of the substrate 103 by the substrate chucking units 119 to 123 are determined. Further, as the control condition in the imprint process, the tilt amount (the tilt X (tₓ) in the X direction and the tilt Y (t_{y}) in the Y direction) of the mold 102 to be adjusted by the mold driving unit MDU is determined.

Note that in step S703, it is preferable to determine the control condition such that the pressure value to be applied to the mold 102 is as large as possible from the viewpoint of the fillability of the imprint material with respect to the mold 102, and the pressure value to be applied to the substrate 103 is as small as possible from the viewpoint of the overlay accuracy. In other words, the pressure values to be applied to the mold 102 and the substrate 103, respectively, are determined such that the pressure value to be applied to the mold 102 is larger than the pressure value to be applied to the substrate 103. More specifically, pₘ, p_{w}, tₓ, and t_{y} that minimize an evaluation function J expressed by following equation (5) are obtained.

$$J = {( p ( {p}_{m} , {p}_{w} , {t}_{x} , {t}_{y} ) - {r}_{d} )}^{2} + {( q ( {p}_{m} , {t}_{x} , {t}_{y} ) - {θ}_{d} )}^{2} + {( {c}_{m \_ max} - {c}_{m} )}^{2} + {c}_{w}^{2} \qquad ( 5 )$$

$$where \{ \begin{matrix}0 < {p}_{m} < {p}_{m \_ max} \\ 0 < {p}_{w} < {p}_{w \_ max} \\ \vert {t}_{x} \vert < {t}_{x \_ max} \\ \vert {t}_{y} \vert < {t}_{y \_ max}\end{matrix}$$

Note that p_{w_max} [kPa] indicates the maximum pressurizing amount (maximum pressure value) applicable to the substrate 103, and p_{m_max} [kPa] indicates the maximum pressurizing amount (maximum pressure value) applicable to the mold 102. Further, t_{x_max} [urad] indicates the maximum tilt amount of the mold 102 in the X direction, and t_{y_max} [urad] indicates the maximum tilt amount of the mold 102 in the Y direction.

In step S704, a control condition in the imprint process is determined such that the contact position to start the contact between the mold 102 and the imprint material on the substrate matches the center position of the mold 102 (pattern region 201 thereof) (the center position of the shot region). More specifically, as the control condition in the imprint process, the pressure value (pressurizing amount pₘ [kPa]) to be applied to the back surface of the mold 102 by the pressure adjustment unit 111 is determined. Note that as for the pressure values to be applied to the back surface of the substrate 103 by the substrate chucking units 119 to 123, respectively, all the values are set to be negative pressures so that the substrate 103 placed on the substrate chuck 124 is chucked (see, FIG. 5A). Further, as for the tilt amount (the tilt X (tₓ) in the X direction and the tilt Y (t_{y}) in the Y direction) of the mold 102 to be adjusted by the mold driving unit MDU is determined such that the mold 102 becomes parallel to the substrate 103.

As has been described above, according to this embodiment, the control condition in the imprint process can be determined such that the contact position to start the contact between the mold 102 and the imprint material on the substrate matches the target position. In other words, in the imprint process, it is possible to determine the control condition for starting the contact with the imprint material on the substrate from the desired position of the mold 102. By performing the imprint process while controlling the pressure adjustment unit 111, the substrate chucking units 119 to 123, and the mold driving unit MDU in accordance with the control condition determined as described above, it is possible to implement more advantageous progress of filling of the mold 102 with the imprint material 301.

Note that in this embodiment, for the partial shot region, the control condition in the imprint process is determined, by using the function (equation (4)) stored in the storage unit STU, such that the contact position to start the contact between the mold 102 and the imprint material on the substrate matches the target position. However, also for the full shot region, the control condition in the imprint process may be determined, by using the function (equation (4)) stored in the storage unit STU, such that the contact position to start the contact between the mold 102 and the imprint material on the substrate matches the target position. In this case, the target position may be set at the center position of the mold 102 (pattern region 201 thereof) as has been described above.

Further, in this embodiment, the case has been described in which the control unit CTU included in the imprint apparatus 1 performs the process (determination method) of determining the condition (control condition) for controlling the pressure adjustment unit 111, the substrate chucking units 119 to 123, and the mold driving unit MDU, but the present invention is not limited to this. For example, this process may be performed in an information processing apparatus outside the imprint apparatus 1 before performing the imprint process. In this case, the imprint apparatus 1 obtains the control condition from the information processing apparatus, and performs the imprint process while controlling the pressure adjustment unit 111, the substrate chucking units 119 to 123, and the mold driving unit MDU in accordance with the control condition.

The pattern of a cured product formed using the imprint apparatus 1 (the imprint method) according to the present embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

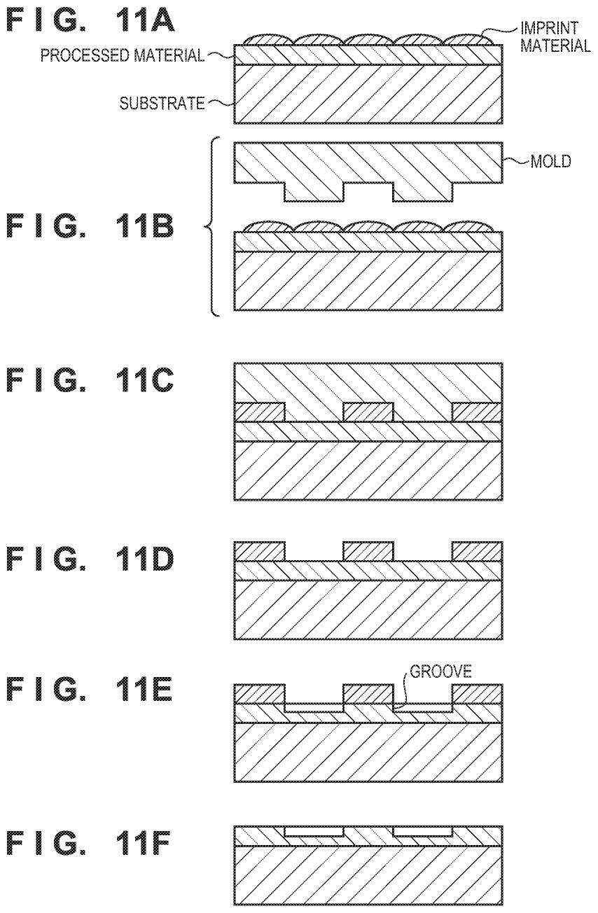

Next, description regarding a detailed method of manufacturing an article is given. As illustrated in FIG. 11A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 11B, a side of the mold for imprint with a projection and groove pattern is formed on and caused to face the imprint material on the substrate. As illustrated in FIG. 11C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 11D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 11E, when etching is performed using the pattern of the cured product as an etching resistant mask, a portion of the surface of the processed material where the cured product does not exist or remains thin is removed to form a groove. As shown in FIG. 11F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-008948 filed on Jan. 24, 2023, which is hereby incorporated by reference herein in its entirety.

What is claimed is:

1. An imprint method of performing an imprint process of forming a pattern of an imprint material on a substrate by using a mold, the method comprising:
performing the imprint process while controlling a deformation unit configured to deform each of the mold and the substrate into a convex shape toward a space between the mold and the substrate by applying a pressure to each of the mold and the substrate, and an adjustment unit configured to adjust a relative tilt between the mold and the substrate; and
determining, before performing the imprint process, by using a function including, as variables, a pressure value applied to the mold, a pressure value applied to the substrate, and a relative tilt amount between the mold and the substrate, and expressing a contact position between the mold and the imprint material on the substrate, pressure values to be applied to the mold and the substrate, respectively, by the deformation unit and a relative tilt amount between the mold and the substrate to be adjusted by the adjustment unit such that a contact position to start a contact between the mold and the imprint material on the substrate matches a target position.

2. The method according to claim 1, wherein
in the determining, the pressure values to be applied to the mold and the substrate, respectively, by the deformation unit are determined such that the pressure value to be applied to the mold is larger than the pressure value to be applied to the substrate.

3. The method according to claim 1, wherein
the substrate includes a partial shot region having a smaller area than a pattern region of the mold, and
in the imprint process with respect to the partial shot region, in the determining, the pressure values to be applied to the mold and the substrate, respectively, by the deformation unit and the relative tilt amount between the mold and the substrate to be adjusted by the adjustment unit are determined, by using the function, such that a contact position to start a contact between the mold and the imprint material on the substrate matches a target position.

4. The method according to claim 3, wherein
the substrate includes a plurality of shot regions including the partial shot region and a full shot region having an area equal to that of the pattern region of the mold, and
the determining includes specifying the partial shot region based on information indicating an array of the plurality of shot regions.

5. The method according to claim 1, wherein
the deformation unit includes
a mold deformation mechanism configured to deform the mold into a convex shape toward a side of the substrate by applying a pressure to a back surface of the mold, and
a substrate deformation mechanism configured to deform the substrate into a convex shape toward a side of the mold by applying a pressure to a back surface of the substrate, and
in the determining, a pressure value to be applied to the back surface of the mold by the mold deformation mechanism, and a pressure value to be applied to the back surface of the substrate by the substrate deformation mechanism are determined such that the contact position to start the contact between the mold and the imprint material on the substrate matches the target position.

6. The method according to claim 1, wherein
the adjustment unit includes a mold driving mechanism configured to tilt the mold with respect to the substrate by driving the mold, and
in the determining, a tilt amount of the mold to be tilted with respect to the substrate by the mold driving mechanism is determined such that the contact position to start the contact between the mold and the imprint material on the substrate matches the target position.

7. An imprint apparatus that performs an imprint process of forming a pattern of an imprint material on a substrate by using a mold, the apparatus comprising:
a deformation unit configured to deform each of the mold and the substrate into a convex shape toward a side of a space between the mold and the substrate by applying a pressure to each of the mold and the substrate;
an adjustment unit configured to adjust a relative tilt between the mold and the substrate;
a storage unit configured to store a function including, as variables, a pressure value applied to the mold, a pressure value applied to the substrate, and a relative tilt amount between the mold and the substrate, and expressing a contact position between the mold and the imprint material on the substrate; and
a control unit configured to determine, by using the function stored in the storage unit, pressure values to be applied to the mold and the substrate, respectively, by the deformation unit and a relative tilt amount between the mold and the substrate to be adjusted by the adjustment unit such that a contact position to start a contact between the mold and the imprint material on the substrate matches a target position, and control, in the imprint process, the deformation unit and the adjustment unit in accordance with the determined pressure values and tilt amount.

8. A determination method of determining a condition for controlling a deformation unit and an adjustment unit included in an imprint apparatus that performs an imprint process of forming a pattern of an imprint material on a substrate by suing a mold, the deformation unit being configured to deform each of the mold and the substrate into a convex shape toward a side of a space between the mold and the substrate by applying a pressure to each of the mold and the substrate, and the adjustment unit being configured to adjust a relative tilt between the mold and the substrate, the method comprising
determining, by using a function including, as variables, a pressure value applied to the mold, a pressure value applied to the substrate, and a relative tilt amount between the mold and the substrate, and expressing a contact position between the mold and the imprint material on the substrate, pressure values to be applied to the mold and the substrate, respectively, by the deformation unit and a relative tilt amount between the mold and the substrate to be adjusted by the adjustment unit such that a contact position to start a contact between the mold and the imprint material on the substrate matches a target position.

9. An information processing apparatus that executes a determination method defined in claim 8.

10. An article manufacturing method comprising:
forming a pattern on a substrate using an imprint method defined in claim 1;
processing the substrate on which the pattern is formed in the forming; and
manufacturing an article from the processed substrate.
